(19) United States
(12) Patent Application Publication
(10) Pub. No.: US 2026/0269564 A1
(43) Pub. Date: Sep. 10, 2026

(54) OPTICAL MODULE

(71) Applicant: Mitsubishi Electric Corporation, Tokyo (JP)

(72) Inventor: Shinichi KANEKO, Tokyo (JP)

(73) Assignee: Mitsubishi Electric Corporation, Tokyo (JP)

(21) Appl. No.: 19/480,014

(22) PCT Filed: Sep. 29, 2023
(86) PCT No.: PCT/JP2023/035617

§ 371 Date: Oct. 29, 2025

(51) Int. Cl. H01S 5/062; G01J 9/00

(52) U.S. Cl. CPC H01S 5/062; G01J 9/00

(57) ABSTRACT

The optical coupler (11) inputs backside light of the light emitting device (7) as incident light. The optical demultiplexer (13) splits the incident light into first and second branched light. The first light receiving device (14) receives the first branched light. The second light receiving device (15) receives the second branched light via the waveguide interferometer (16). The control unit (8) adjusts a current of the light emitting device (7) so that a light receiving current of the first light receiving device (14) becomes constant, and adjusts temperature of the light emitting device (7) so that a value by dividing a light receiving current of the second light receiving device (15) by the light receiving current of the first light receiving device (14) becomes constant. A surface protective film (20) covers the surface of the semiconductor substrate (10) to prevent the backside light from entering the semiconductor substrate (10).

### FIELD

The present disclosure relates to an optical module incorporating a wavelength monitor chip that monitors backside light of a light emitting device.

### BACKGROUND ART

Along with the spread of the Internet, an increase in capacity of an optical communication system is being promoted. As a large-capacity optical communication system, a dense wavelength division multiplexing (DWDM) system, which densely multiplexes optical signals at predetermined wavelength intervals, a digital coherent system, which carries a plurality of pieces of information in one modulation by carrying information not only in intensity modulation but also in phase, or the like has been introduced. In the DWDM system, in order to reduce filter loss of a signal and crosstalk between channels, it is required to control the wavelength to match the wavelength with a predetermined wavelength with high accuracy. Even in the digital coherent system, it is also required to match wavelengths of a transmitted or received optical signal and local light to cause interference, and hence it is required to control the wavelength to match the wavelength with a predetermined wavelength with high accuracy.

Meanwhile, a light emitting device such as a laser diode that is a light source of the optical communication system has such a characteristic that its wavelength changes depending on temperature, a drive current, or the like. In view of the above, a wavelength monitor chip monitors backside light of the light emitting device, and the light emitting device is controlled based on results of the monitoring. In the wavelength monitor chip, a grating coupler inputs the backside light of the light emitting device as incident light and couples the backside light to an optical waveguide (see, for example, Patent Literature 1).

### CITATION LIST

### Patent Literature

[PTL 1] JP 5969811 B

### SUMMARY

### Technical Problem

However, the coupling efficiency of the grating coupler is not high, and most of incident light is not coupled with the waveguide but enters a semiconductor substrate to become stray light. A waveguide light receiving device in the wavelength monitor chip receives not only light propagating through the waveguide, but also stray light propagating through the semiconductor substrate. This causes noise in a light receiving current of the light receiving device, and hence there has been a problem in that the control accuracy of the light emitting device is reduced.

The present disclosure has been made to solve the above-mentioned problem, and has an object to provide an optical module that makes it possible to improve a control accuracy of a light emitting device.

### Solution to Problem

An optical module according to the present disclosure includes: a light emitting device; a wavelength monitor chip monitoring backside light of the light emitting device; and a control unit controlling the light emitting device based on a monitoring result of the wavelength monitor chip, wherein the wavelength monitor chip includes a semiconductor substrate, an optical coupler, an optical demultiplexer, first and second light receiving devices, and a waveguide interferometer which are formed on a surface of the semiconductor substrate, and a surface protective film covering the surface of the semiconductor substrate to prevent the backside light from entering the semiconductor substrate, the optical coupler inputs the backside light as incident light, the optical demultiplexer splits the incident light into first branched light and second branched light, the first light receiving device receives the first branched light, the second light receiving device receives the second branched light via the waveguide interferometer, and the control unit adjusts a current of the light emitting device so that a light receiving current of the first light receiving device becomes constant, obtains a value by dividing a light receiving current of the second light receiving device by the light receiving current of the first light receiving device, and adjusts temperature of the light emitting device so that the value becomes constant.

### Advantageous Effects of Invention

In the present disclosure, the surface protective film is formed on the surface of the wavelength monitor chip. The surface protective film prevents light from entering the semiconductor substrate, and hence stray light can be reduced. This makes it possible to improve the control accuracy of the light emitting device.

### BRIEF DESCRIPTION OF THE DRAWINGS

FIG. 1 is a side view illustrating an optical module according to a first embodiment.

FIG. 2 is a perspective view illustrating the wavelength monitor chip according to the first embodiment.

FIG. 3 is a perspective view illustrating a state in which a surface protective film is omitted from the wavelength monitor chip of FIG. 2.

FIG. 4 is a cross-sectional view taken along the line I-II of FIG. 2.

FIG. 5 is a cross-sectional view taken along the line III-IV of FIG. 2.

FIG. 6 is a graph illustrating a relationship between the wavelength of the incident light and the light receiving current of the second light receiving device.

FIG. 7 is a view illustrating an operation of an optical module according to the comparative example.

FIG. 8 is a graph illustrating a relationship between the wavelength of incident light and the light receiving current of the light receiving device in the comparative example.

FIG. 9 is a perspective view illustrating a wavelength monitor chip according to a second embodiment.

FIG. 10 is a perspective view illustrating a wavelength monitor chip according to a third embodiment.

FIG. 11 is a perspective view illustrating a wavelength monitor chip according to a fourth embodiment.

### DESCRIPTION OF EMBODIMENTS

An optical module according to the embodiments of the present disclosure will be described with reference to the drawings. The same components will be denoted by the same symbols, and the repeated description thereof may be omitted.

### First Embodiment

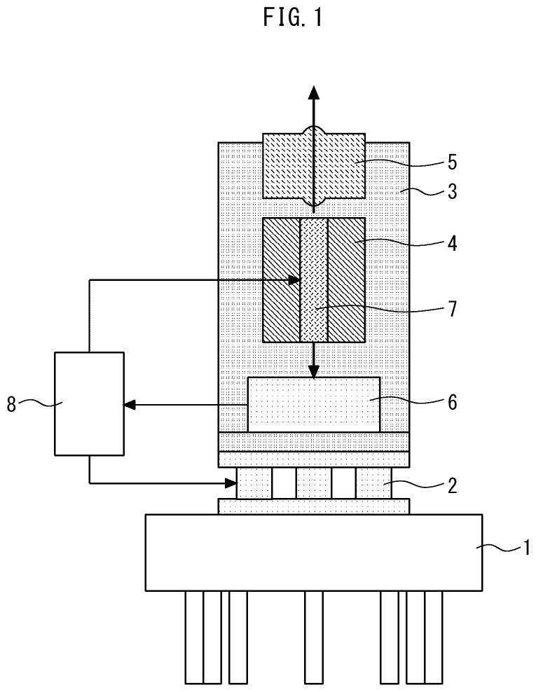

FIG. 1 is a side view illustrating an optical module according to a first embodiment. A Peltier device 2, which is a thermoelectric device, is formed on a stem 1. A block 3 is formed on the Peltier device 2. A submount 4, a lens 5, and a wavelength monitor chip 6 are formed on a side surface of the block 3. A light emitting device 7, such as a laser diode, is formed on the submount 4. The lens 5 converts light emitted from the light emitting device 7 into parallel light. A lens (not shown) formed on a cap focuses the parallel light to an optical fiber. In this manner, the light emitted from the light emitting device 7 is used as a light source of an optical communication system. The wavelength monitor chip 6 monitors backside light of the light emitting device 7. A control unit 8 controls the Peltier device 2 and the light emitting device 7 based on monitoring results of the wavelength monitor chip 6.

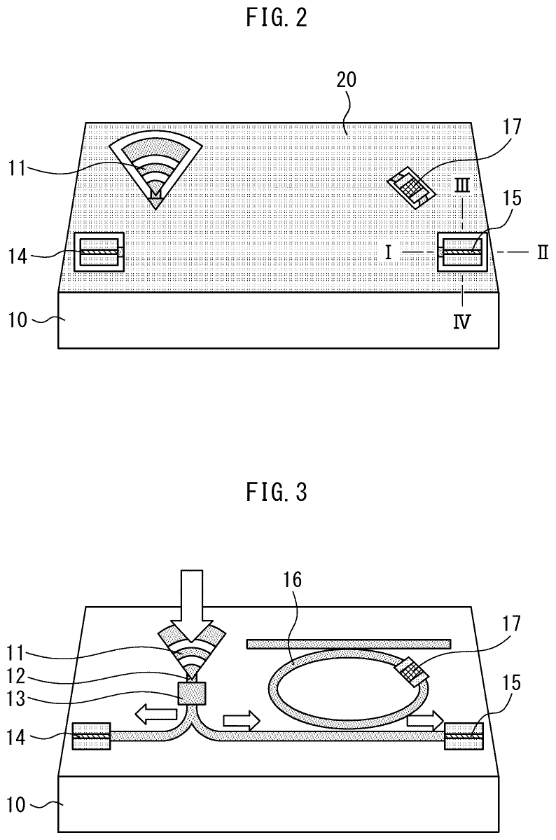

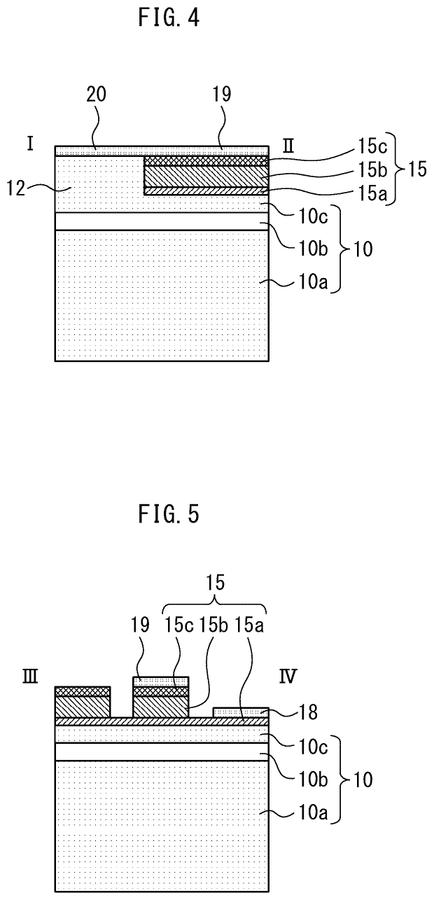

FIG. 2 is a perspective view illustrating the wavelength monitor chip according to the first embodiment. FIG. 3 is a perspective view illustrating a state in which a surface protective film is omitted from the wavelength monitor chip of FIG. 2. FIG. 4 is a cross-sectional view taken along the line I-II of FIG. 2. FIG. 5 is a cross-sectional view taken along the line III-IV of FIG. 2.

As illustrated in FIG. 4 and FIG. 5, a semiconductor substrate 10 is an SOI substrate in which a SiO₂ layer 10b and a Si layer 10c are sequentially stacked on a Si substrate 10a. An optical coupler 11, an optical waveguide 12, an optical demultiplexer 13, first and second waveguide light receiving devices 14 and 15, a waveguide interferometer 16, and a phase adjustment section 17 are formed on the surface of the semiconductor substrate 10, and are monolithically integrated.

The optical coupler 11 is, for example, a grating coupler, and inputs the backside light of the light emitting device 7 as incident light to couple the backside light to the optical waveguide 12. The optical demultiplexer 13 is, for example, an MMI (Multimode interference) coupler, and splits the incident light into first branched light and second branched light.

The first light receiving device 14 receives the first branched light. The light receiving current of the first light receiving device 14 reflects the optical output of the light emitting device 7. The second light receiving device 15 receives the second branched light via the waveguide interferometer 16. The light receiving current of the second light receiving device 15 reflects the oscillation wavelength of the light emitting device 7. The waveguide interferometer 16 is a ring resonator including a straight waveguide and a ring waveguide. The phase adjustment section 17 is, for example, a heater formed of a thin-film resistor.

As illustrated in FIG. 4 and FIG. 5, the second light receiving device 15 is a photodiode including a p-type Ge layer 15a, an i-type Ge light absorbing layer 15b, and an n-type Ge layer 15c sequentially stacked on the semiconductor substrate 10. An electrode 18 is formed on the p-type Ge layer 15a, and an electrode 19 is formed on the n-type Ge layer 15c. The first light receiving device 14 is also a photodiode having a similar configuration.

When the optical output of the light emitting device 7 changes, the reception characteristics change. Accordingly, the control unit 8 adjusts the current of the light emitting device 7 so that the light receiving current of the first light receiving device 14 of the wavelength monitor chip 6 becomes constant, to thereby keep the optical output of the light emitting device 7 constant.

The light propagating through the ring waveguide of the waveguide interferometer 16 and the light propagating through the straight waveguide interfere with each other, resulting in constructive or destructive interference. The transmittance of the waveguide interferometer 16 is determined by the phase relationship (relative phase) between the interfering light beams, and thus has such a characteristic that peaks and valleys are repeated with respect to the wavelength. The oscillation wavelength is monitored by using this wavelength dependency of the transmittance. The wavelength change can be detected most efficiently when the slope of the transmittance of the waveguide interferometer 16 with respect to the wavelength is increased. In view of the above, the phase adjustment section 17 heats a part of the ring waveguide to change the length and refractive index of the waveguide, to thereby change the phase of the light propagating through the ring waveguide. This makes it possible to change the transmittance with respect to the wavelength, and thus makes adjustment possible so that the slope of the transmittance with respect to a desired wavelength is increased. It is to be noted that the heater adjusts the temperature of a part of the waveguide of the waveguide interferometer 16, but the temperature of the entire waveguide of the waveguide interferometer 16 may be adjusted. Further, the phase adjustment section 17 is not limited to a heater, and may be means for changing a refractive index of a waveguide material by applying an electric field.

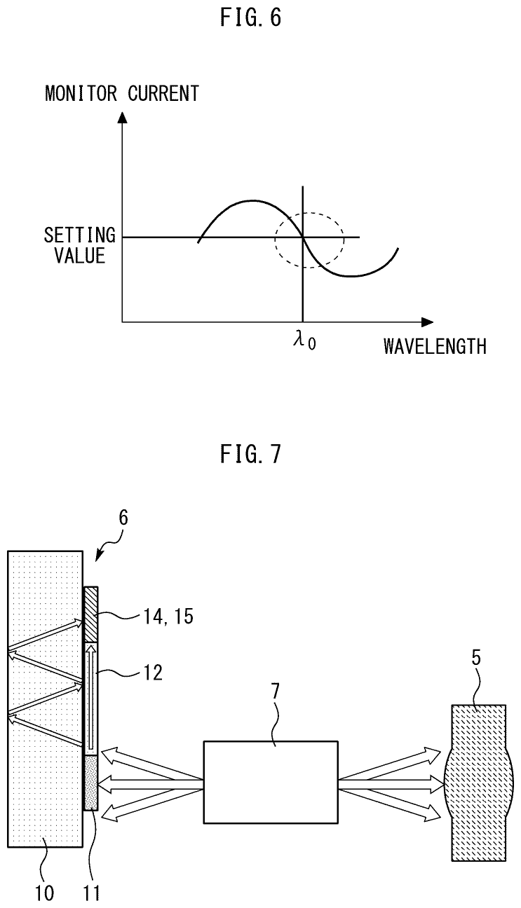

FIG. 6 is a graph illustrating a relationship between the wavelength of the incident light and the light receiving current of the second light receiving device. The transmittance of the waveguide interferometer 16 positioned before the second light receiving device 15 has a characteristic that periodically repeats peaks and valleys with respect to the wavelength of the incident light. Accordingly, the light receiving current of the second light receiving device 15 changes in accordance with the wavelength of the incident light. The phase adjustment section 17 adjusts the refractive index of the waveguide material so that a setting value of the light receiving current comes to this part having a large change.

The optical output of the light emitting device 7 may change over time. Accordingly, even when the temperature of the light emitting device 7 is adjusted so that the light receiving current of the second light receiving device 15 becomes constant, the wavelength is not always constant, and there is a possibility of causing a wavelength shift. In view of the above, the control unit 8 obtains the transmittance by dividing the light receiving current of the second light receiving device 15 by the light receiving current of the first light receiving device 14 corresponding to the optical output of the light emitting device 7, and adjusts the temperature of the light emitting device 7 by the Peltier device 2 so that this value becomes constant. This makes it possible to keep the oscillation wavelength of the light emitted from the light emitting device 7 to a predetermined wavelength. For example, when the wavelength of the light emitted from the light emitting device 7 is set to λ₀, the wavelength can be kept to λ₀ by adjusting the temperature of the light emitting device 7 so that the transmittance of the waveguide interferometer 16 becomes T₀.

A metal film 20 covers the surface of the semiconductor substrate 10 as a surface protective film. The metal film 20 prevents the backside light of the light emitting device 7 from entering the semiconductor substrate 10. Openings are formed in the metal film 20, and a light receiving section of the optical coupler 11, which is an optical input section of the wavelength monitor chip 6, output electrodes for the light receiving signals of the first and second light receiving devices 14 and 15, which are electrical signal output sections of the wavelength monitor chip 6, and the like are exposed from the metal film 20. The optical demultiplexer 13, the optical waveguide 12, the waveguide interferometer 16, and the like are covered with the metal film 20.

Subsequently, the effect of this embodiment is described in comparison with a comparative example. FIG. 7 is a view illustrating an operation of an optical module according to the comparative example. In the comparison, no metal film 20 is formed on the surface of the wavelength monitor chip 6. The coupling efficiency of the optical coupler 11 is not high, and most of incident light enters the semiconductor substrate 10 without being coupled to the optical waveguide 12, and becomes stray light. The first and second light receiving devices 14 and 15 of the wavelength monitor chip 6 receive not only light propagating through the optical waveguide 12, but also stray light propagating through the semiconductor substrate 10.

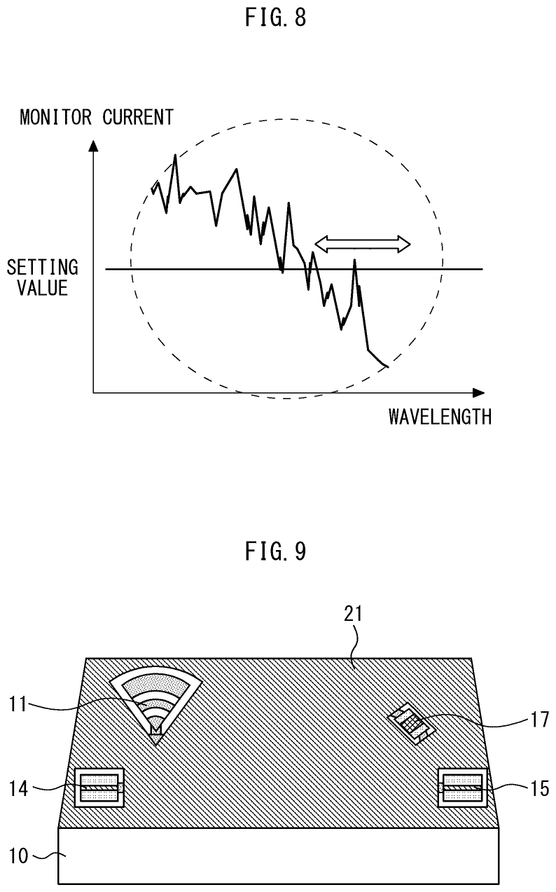

FIG. 8 is a graph illustrating a relationship between the wavelength of incident light and the light receiving current of the light receiving device in the comparative example. FIG. 8 corresponds to a part surrounded by the broken line in FIG. 6. When the first and second light receiving devices 14 and 15 receive stray light, noise is introduced to the light receiving current. When the light emitting device 7 is controlled based on this light receiving current, the control accuracy is reduced.

In contrast, in this embodiment, the metal film 20 is formed on the surface of the wavelength monitor chip 6. The metal film 20 prevents light from entering the semiconductor substrate 10, and hence stray light can be reduced. This makes it possible to improve the control accuracy of the light emitting device 7.

Further, it is preferable that the material and thickness of the metal film 20 be the same as those of the electrodes 18 and 19 of the first and second light receiving devices 14 and 15. In this case, the metal film 20 and the electrodes 18 and 19 of the first and second light receiving devices 14 and 15 can be formed simultaneously, and hence the metal film 20 can be formed without increasing the number of manufacturing steps.

### Second Embodiment

FIG. 9 is a perspective view illustrating a wavelength monitor chip according to a second embodiment. In place of the metal film 20, a light absorbing layer 21 is formed on the surface of the semiconductor substrate 10 of the wavelength monitor chip 6 as a surface protective film. The light absorbing layer 21 absorbs the backside light of the light emitting device 7 to prevent light from entering the semiconductor substrate 10, and thus stray light can be reduced. This makes it possible to improve the control accuracy of the light emitting device 7. It is to be noted that the light absorbing layer 21 may be made of the same material as the light absorbing layers of the first and second light receiving devices 14 and 15. Other configurations and effects are similar to those of the first embodiment.

### Third Embodiment

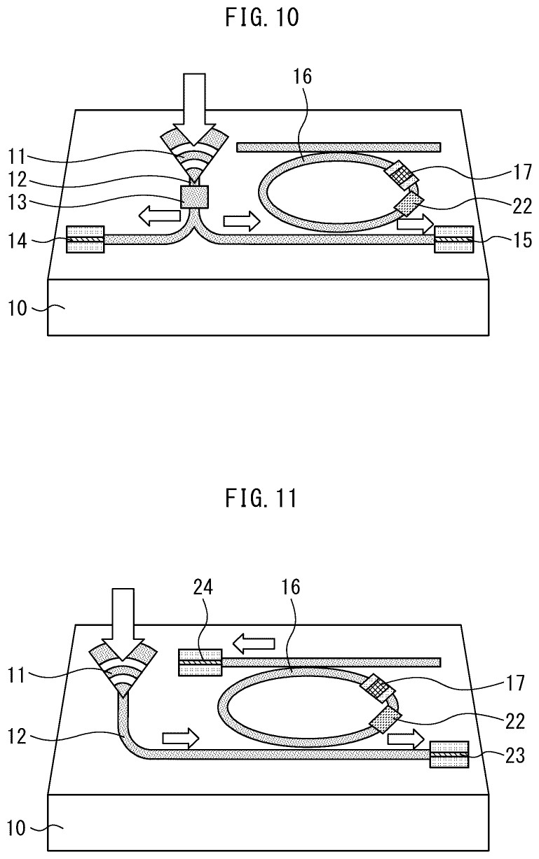

FIG. 10 is a perspective view illustrating a wavelength monitor chip according to a third embodiment. Unlike the first and second embodiments, no surface protective film is formed, and a phase modulation section 22 utilizing the Pockels effect or the like is formed in a part of the ring waveguide of the waveguide interferometer 16. It is to be noted that the phase adjustment section 17 may be used as the phase modulation section 22. Other configurations of the wavelength monitor chip and the optical module are similar to those of the first embodiment.

The phase modulation section 22 applies a pilot signal that is a modulated wave such as a sine wave (applies a dither) to the light propagating through the ring waveguide of the waveguide interferometer 16. This makes it possible to apply phase modulation only to the light that has passed through the ring waveguide of the waveguide interferometer 16, and no phase modulation is applied to stray light that does not pass through the ring waveguide. It is to be noted that, when the pilot signal is 1 kHz or less, a heater can be used as the phase modulation section 22. When the phase modulation section 22 uses an electric field, the frequency range of the pilot signal can be expanded.

The second light receiving device 15 receives the second branched light via the waveguide interferometer 16. The oscillation wavelength of the light emitting device 7 can be monitored by detecting only the light receiving current modulated in accordance with the pilot signal. The control unit 8 controls the temperature of the light emitting device 7 so that the value obtained by dividing the modulated signal component of the light receiving current of the second light receiving device 15 modulated in accordance with this pilot signal by the light receiving current of the first light receiving device 14 becomes constant (that is, the transmittance of the waveguide interferometer 16 becomes constant). This makes it possible to keep the oscillation wavelength of the light emitting device 7 constant.

Subsequently, the effect of this embodiment is described in comparison with a comparative example. In the comparative example, no pilot signal is applied. In this case, the transmittance of the ring resonator of the waveguide interferometer 16 is calculated as follows. The temperature of the light emitting device 7 is controlled so that this transmittance becomes constant.

$$( TRANSMITTANCE ) = \frac{{I}_{1} + {i}_{i}}{{I}_{0} + {i}_{0}} \dot{{=}_{.}} \frac{{I}_{1} + {i}_{i}}{{I}_{0}} ( 1 - \frac{{i}_{0}}{{I}_{0}} ) \dot{{=}_{.}} \frac{{l}_{1}}{{I}_{0}} ( 1 - \frac{{i}_{0}}{{I}_{0}} + \frac{{i}_{1}}{{I}_{1}} )$$

Here, symbol I₀ represents a DC component of the light receiving current of the first light receiving device 14. Symbol i₀ represents a stray light component of the light receiving current of the first light receiving device 14. Symbol I₁ represents a DC component of the light receiving current of the second light receiving device 15. Symbol in represents a stray light component of the light receiving current of the second light receiving device 15. It is to be noted that, although the stray light is large, the size of the light receiving device is small, and hence the received stray light is smaller than the light propagating through the waveguide. Accordingly, the above approximation calculation is possible.

The noise component caused by stray light in the comparative example is expressed as follows.

$$\frac{{σ}_{0}}{{I}_{0}} + \frac{{σ}_{1}}{{I}_{1}} \to \frac{{σ}_{0}}{{I}_{0}} + \frac{2 {σ}_{1}}{{I}_{0}} \to \frac{\sqrt{5}}{{I}_{0}} σ$$

Here, symbol σ₀ represents a standard deviation of the variation of i₀. Symbol σ₁ represents a standard deviation of the variation of i₁. Symbol σ represents a standard deviation of the variation in the stray light component i of the light receiving current. However, it is assumed that the stray light components received by all of the light receiving devices are the same, and approximation of σ₀≈σ₁≈σ is performed. The incident light is split into half by the optical demultiplexer 13, and hence it is assumed that the transmittance of the ring resonator is set to 50%, and approximation of I₀≈2I₁ is performed. Finally, the variations are combined by taking the square root of the sum of the squares of the standard deviations of the respective variations.

In contrast, in this embodiment, only the light receiving current modulated in accordance with the pilot signal is detected to monitor the oscillation wavelength of the light emitting device 7. In this case, the transmittance of the ring resonator of the waveguide interferometer 16 is calculated as follows.

$$( TRANSMITTANCE ) = \frac{{S}_{1}}{{I}_{0} + {i}_{0}} \dot{{=}_{.}} \frac{{S}_{1}}{{I}_{0}} ( 1 - \frac{{i}_{0}}{{I}_{0}} )$$

Here, symbol S₁ represents a modulated signal component of the light receiving current of the second light receiving device 15. As a result, the noise component caused by stray light in this embodiment is σ/I₀, which is smaller than the noise component √5σ/I₀ in the comparative example. Accordingly, it is understood that, in this embodiment, the effect of noise caused by stray light is smaller than that in the comparative example, and the wavelength control accuracy is improved.

As described above, in this embodiment, the temperature of the light emitting device 7 is controlled so that the value obtained by dividing the modulated signal component of the light receiving current of the second light receiving device 15 modulated in accordance with the pilot signal by the light receiving current of the first light receiving device 14 becomes constant. This makes it possible to eliminate the influence of the stray light, and thus the control accuracy of the oscillation wavelength of the light emitting device 7 can be improved.

### Fourth Embodiment

FIG. 11 is a perspective view illustrating a wavelength monitor chip according to a fourth embodiment. Unlike the third embodiment, without using the optical demultiplexer 13, the optical coupler 11, the optical waveguide 12, first and second waveguide light receiving devices 23 and 24, and the waveguide interferometer 16 are formed on the surface of the semiconductor substrate 10, and are monolithically integrated.

The optical coupler 11 inputs the backside light of the light emitting device 7 as incident light and couples the backside light to the optical waveguide 12. The first light receiving device 23 is formed at an output port (through port) on the input side of the waveguide interferometer 16. The second light receiving device 24 is formed at an output port (cross port) on the output side of the waveguide interferometer 16.

The phase modulation section 22 applies a pilot signal that is a modulated wave such as a sine wave (applies a dither) to the light propagating through the ring waveguide of the waveguide interferometer 16. This makes it possible to apply phase modulation only to the light that has passed through the ring waveguide of the waveguide interferometer 16, and no phase modulation is applied to stray light that does not pass through the ring waveguide. The first light receiving device 23 and the second light receiving device 24 receive the incident light via the waveguide interferometer 16.

The wavelength dependences on the transmittance observed in the first light receiving device 23 and the second light receiving device 24 are inverse to each other. Further, the loss in the waveguide of the waveguide interferometer 16 is small and ignorable. Accordingly, the sum of the light receiving current of the first light receiving device 23 and the light receiving current of the second light receiving device 24 does not depend on the wavelength, but reflects the optical output of the light emitting device 7. The control unit 8 controls the current of the light emitting device 7 so that this sum becomes constant. This makes it possible to keep the optical output of the light emitting device 7 constant.

Further, the modulated signal components of the light receiving currents of the first light receiving device 23 and the second light receiving device 24 are also inverse to each other, and their magnitudes reflect the slope of the transmittance. In view of the above, the control unit 8 adjusts the temperature of the light emitting device 7 so that a value obtained by dividing the sum obtained by adding together, in opposite phases, the modulated signal component of the light receiving current of the first light receiving device 23 and the modulated signal component of the light receiving current of the second light receiving device 24 by the sum of the light receiving current of the first light receiving device 23 and the light receiving current of the second light receiving device 24 becomes constant. This makes it possible to keep the oscillation wavelength of the light emitting device 7 constant.

In this embodiment, the oscillation wavelength of the light emitting device 7 is monitored by detecting the modulated signal components of the light receiving currents of the first and second light receiving devices 23 and 24 modulated in accordance with the pilot signal, and hence the transmittance of the ring resonator of the waveguide interferometer 16 is calculated as follows.

$$( TRANSMITTANCE ) = \frac{{S}_{1} + {S}_{2}}{{I}_{1} + {i}_{1} + {I}_{2} + {i}_{2}} \dot{{=}_{.}} \frac{{S}_{1} + {S}_{2}}{{I}_{1} + {I}_{2}} ( 1 - \frac{{i}_{1} + {i}_{2}}{{I}_{1} + {I}_{2}} )$$

Here, symbol I₁ represents a DC component of the light receiving current of the first light receiving device 23. Symbol i₁ represents a stray light component of the light receiving current of the first light receiving device 23. Symbol S₁ represents a modulated signal component of the light receiving current of the first light receiving device 23. Symbol I₂ represents a DC component of the light receiving current of the second light receiving device 24. Symbol i₂ represents a stray light component of the light receiving current of the second light receiving device 24. Symbol S₂ represents a modulated signal component of the light receiving current of the second light receiving device 24.

The noise component caused by stray light in this embodiment is expressed as follows.

$$\frac{{σ}_{1}}{{I}_{1} + {I}_{2}} + \frac{{σ}_{2}}{{I}_{1} + {I}_{2}} \to \frac{σ}{\sqrt{2} {I}_{0}}$$

The noise component σ/√2I₀ caused by stray light in this embodiment is smaller than the noise component √5σ/I₀ in the comparative example. Accordingly, it is understood that the influence of noise caused by stray light is smaller in this embodiment than in the comparative example, and the wavelength control accuracy is improved.

As described above, in this embodiment, the current of the light emitting device 7 is controlled so that the sum of the light receiving currents of the first light receiving device 23 on the through port side and the second light receiving device 24 on the cross port side becomes constant. This makes it possible to keep the optical output of the light emitting device 7 constant. Further, the temperature of the light emitting device 7 is controlled so that the value obtained by dividing the sum obtained by adding together, in opposite phases, the modulated signal components of the light receiving currents of the first and second light receiving devices 23 and 24 modulated in accordance with the pilot signal by the sum of the light receiving currents of the first and second light receiving devices 23 and 24 becomes constant. This makes it possible to keep the oscillation wavelength of the light emitting device 7 constant.

Further, no optical demultiplexer 13 is formed, and hence the wavelength monitor chip 6 can be downsized. In addition, the oscillation wavelength of the light emitting device 7 is monitored by detecting only the light receiving current modulated in accordance with the pilot signal, and hence the influence of the stray light can be eliminated. Moreover, the modulated signal components are doubled by monitoring the sum obtained by adding together, in opposite phases, the modulated signal components of the light receiving currents of the first and second light receiving devices 23 and 24, and hence the wavelength control accuracy is improved.

### REFERENCE SIGNS LIST

7 light emitting device; 6 wavelength monitor chip; 8 control unit; 10 semiconductor substrate; 11 optical coupler; 13 optical demultiplexer; 14 first light receiving device; 15 second light receiving device; 16 waveguide interferometer; 18,19 electrode; 20 metal film (surface protective film); 21 light absorbing layer (surface protective film); 22 phase modulation section; 23 first light receiving device; 24 second light receiving device

1. An optical module comprising:
a light emitting device;
a wavelength monitor chip monitoring backside light of the light emitting device; and
a control unit controlling the light emitting device based on a monitoring result of the wavelength monitor chip,
wherein the wavelength monitor chip includes
a semiconductor substrate,
an optical coupler, an optical demultiplexer, first and second light receiving devices, and a waveguide interferometer which are formed on a surface of the semiconductor substrate, and
a surface protective film covering the surface of the semiconductor substrate to prevent the backside light from entering the semiconductor substrate,
the optical coupler inputs the backside light as incident light,
the optical demultiplexer splits the incident light into first branched light and second branched light,
the first light receiving device receives the first branched light,
the second light receiving device receives the second branched light via the waveguide interferometer, and
the control unit adjusts a current of the light emitting device so that a light receiving current of the first light receiving device becomes constant, obtains a value by dividing a light receiving current of the second light receiving device by the light receiving current of the first light receiving device, and adjusts temperature of the light emitting device so that the value becomes constant.

2. The optical module according to claim 1, wherein the surface protective film is a metal film.

3. The optical module according to claim 2, wherein material and thickness of the metal film is the same as those of electrodes of the first and second light receiving devices.

4. The optical module according to claim 1, wherein the surface protective film is a light absorbing layer which absorbs the backside light.

5. An optical module comprising:
a light emitting device;
a wavelength monitor chip monitoring backside light of the light emitting device; and
a control unit controlling the light emitting device based on a monitoring result of the wavelength monitor chip,
wherein the wavelength monitor chip includes
a semiconductor substrate, and
an optical coupler, an optical demultiplexer, first and second light receiving devices, a waveguide interferometer, and a phase modulation section which are formed on a surface of the semiconductor substrate,
the optical coupler inputs the backside light as incident light,
the optical demultiplexer splits the incident light into first branched light and second branched light,
the first light receiving device receives the first branched light,
the phase modulation section applies a pilot signal to light propagating through a ring waveguide of the waveguide interferometer,
the second light receiving device receives the second branched light via the waveguide interferometer, and
the control unit adjusts a current of the light emitting device so that a light receiving current of the first light receiving device becomes constant, obtains a value by dividing a modulated signal component of a light receiving current of the second light receiving device modulated in accordance with the pilot signal by the light receiving current of the first light receiving device, and adjusts temperature of the light emitting device so that the value becomes constant.

6. An optical module comprising:
a light emitting device;
a wavelength monitor chip monitoring backside light of the light emitting device; and
a control unit controlling the light emitting device based on a monitoring result of the wavelength monitor chip,
wherein the wavelength monitor chip includes
a semiconductor substrate, and
an optical coupler, first and second light receiving devices, a waveguide interferometer, and a phase modulation section which are formed on a surface of the semiconductor substrate,
the optical coupler inputs the backside light as incident light,
the first light receiving device is formed at a through port of the waveguide interferometer,
the second light receiving device is formed at a cross port of the waveguide interferometer,
the first light receiving device and the second light receiving device receive the incident light via the waveguide interferometer,
the phase modulation section applies a pilot signal to light propagating through a ring waveguide of the waveguide interferometer, and
the control unit controls a current of the light emitting device so that a sum of light receiving currents of the first light receiving device and the second light receiving device becomes constant, obtains a value by dividing a sum obtained by adding together, in opposite phases, modulated signal components of light receiving currents of the first and second light receiving devices modulated in accordance with the pilot signal by a sum of the light receiving currents of the first and second light receiving devices, and controls temperature of the light emitting device so that the value becomes constant.
